(19) United States
(12) Patent Application Publication
(10) Pub. No.: US 2024/0423059 A1
(43) Pub. Date: Dec. 19, 2024

(54) DISPLAY ELEMENT AND DISPLAY DEVICE

(71) Applicant: Sony Semiconductor Solutions Corporation, Kanagawa (JP)

(72) Inventors: Chugen Hamachi, Tokyo (JP); Mitsuru Asano, Kanagawa (JP); Yosuke Motoyama, Kanagawa (JP); Keiichi Yagi, Kanagawa (JP)

(21) Appl. No.: 18/704,682

(22) PCT Filed: Nov. 22, 2022
(86) PCT No.: PCT/JP2022/043129

§ 371 Date: Apr. 25, 2024

(30) Foreign Application Priority Data
Dec. 10, 2021 (JP) 2021-201079

(51) Int. Cl. H10K 59/38; H10K 59/80

(52) U.S. Cl. CPC H10K 59/38; H10K 59/879

(57) ABSTRACT

Improved image quality for display elements with an inclined optical axis of emission light is disclosed. In one example, a display element includes pixel array portion with pixels each including subpixels that respectively include a light emitting portion and a color filter that transmits emission light of a predetermined wavelength among pieces of the emission light from the light emitting portion. The color filters are displaced with respect to centers of the light emitting portions. The displacement of the color filters varies among the subpixels.

### FIELD

The present disclosure relates to a display element and a display device.

### BACKGROUND

A display device that is arranged on a head mounted display (HMD) or the like and that displays an image of augmented reality (AR) or virtual reality (VR) to a user is used. A display element used in such a display device is configured to be relatively small. A light beam from the display element is enlarged by an absorption lens and guided to a user. As a result, the user can recognize, as a display image, a virtual image based on the guided light beam. In the display element used for such an application, it is preferable to incline an optical axis of emission light emitted from a region other than a central portion. This is because the virtual image displayed to the user can be further enlarged. Thus, a display element in which a color filter arranged in a pixel of the display element is arranged in a manner of being displaced with respect to a light emitting portion of the pixel has been proposed (see, for example, Patent Literature 1).

### CITATION LIST

### Patent Literature

Patent Literature 1: Japanese Patent Application Laid-open No. 2015-028780

### SUMMARY

### Technical Problem

However, in the above-described conventional technology, there is a problem that image quality by the emission light is deteriorated. In the display element according to the conventional technology described above, subpixels that emit red light, green light, and blue light are arranged in pixels, and a color image is displayed. The color filters of these subpixels are arranged in a displaced manner as described above. At this time, there is a problem that optical axes of emission light of the subpixels are displaced due to a difference in wavelengths of the emission light and display image quality is deteriorated.

Thus, the present disclosure proposes a display element that improves display image quality in a display element in which an optical axis of emission light is inclined.

### Solution to Problem

A display element according to the present disclosure includes: a pixel array portion in which a plurality of pixels is arranged, each of the pixels including a plurality of subpixels each of which includes a light emitting portion and a color filter that transmits emission light of a predetermined wavelength among pieces of the emission light from the light emitting portion, wherein the plurality of pixels includes the plurality of subpixels respectively including the color filters corresponding to different wavelengths, and the pixel array portion includes at least one of the pixels in which the color filters are arranged in a manner of being displaced with respect to centers of the own light emitting portions and the displacement in the arrangement of the color filters vary depending on each of the plurality of subpixels.

### BRIEF DESCRIPTION OF DRAWINGS

FIG. 1 is a view illustrating a configuration example of a display device according to an embodiment of the present disclosure.

FIG. 2 is a view illustrating a configuration example of a display element according to the embodiment of the present disclosure.

FIG. 3 is a view illustrating a configuration example of a pixel according to the embodiment of the present disclosure.

FIG. 4 is a view illustrating a configuration example of a pixel array portion according to a first embodiment of the present disclosure.

FIG. 5A is a plan view illustrating a configuration example of a pixel according to the first embodiment of the present disclosure.

FIG. 5B is a plan view illustrating a configuration example of the pixel according to the first embodiment of the present disclosure.

FIG. 6A is a graph for describing a luminance characteristic of a subpixel according to the first embodiment of the present disclosure.

FIG. 6B is a graph for describing the luminance characteristic of the subpixel according to the first embodiment of the present disclosure.

FIG. 7A is a plan view illustrating a configuration example of a pixel according to a second embodiment of the present disclosure.

FIG. 7B is a plan view illustrating a configuration example of the pixel according to the second embodiment of the present disclosure.

FIG. 8 is a plan view illustrating an arrangement example of the pixel according to the second embodiment of the present disclosure.

FIG. 9 is a plan view illustrating a configuration example of a pixel according to a modification example of the embodiment of the present disclosure.

FIG. 10 is a plan view illustrating a configuration example of a pixel according to a modification example of the embodiment of the present disclosure.

FIG. 11 is a plan view illustrating a configuration example of a pixel according to a modification example of the embodiment of the present disclosure.

FIG. 12 is a plan view illustrating a configuration example of a pixel according to a modification example of the embodiment of the present disclosure.

FIG. 13 is a plan view illustrating a configuration example of a pixel according to a modification example of the embodiment of the present disclosure.

FIG. 14 is a plan view illustrating a configuration example of a pixel according to a modification example of the embodiment of the present disclosure.

FIG. 15 is a plan view illustrating a configuration example of a pixel according to a modification example of the embodiment of the present disclosure.

FIG. 16 is a plan view illustrating a configuration example of a pixel according to a modification example of the embodiment of the present disclosure.

FIG. 17 is a plan view illustrating a configuration example of a pixel according to a modification example of the embodiment of the present disclosure.

FIG. 18 is a plan view illustrating a configuration example of a pixel according to a modification example of the embodiment of the present disclosure.

FIG. 19 is a plan view illustrating a configuration example of a pixel according to a modification example of the embodiment of the present disclosure.

FIG. 20 is a plan view illustrating a configuration example of a pixel according to a modification example of the embodiment of the present disclosure.

FIG. 21 is a plan view illustrating a configuration example of a pixel according to a modification example of the embodiment of the present disclosure.

FIG. 22 is a plan view illustrating a configuration example of a pixel according to a modification example of the embodiment of the present disclosure.

FIG. 23 is a plan view illustrating a configuration example of a pixel according to a modification example of the embodiment of the present disclosure.

FIG. 24 is a plan view illustrating a configuration example of a pixel according to a modification example of the embodiment of the present disclosure.

FIG. 25 is a plan view illustrating a configuration example of a pixel according to a modification example of the embodiment of the present disclosure.

FIG. 26 is a plan view illustrating a configuration example of a pixel according to a modification example of the embodiment of the present disclosure.

FIG. 27 is a plan view illustrating a configuration example of a pixel according to a modification example of the embodiment of the present disclosure.

### DESCRIPTION OF EMBODIMENTS

In the following, embodiments of the present disclosure will be described in detail on the basis of the drawings. The description will be made in the following order. Note that in each of the following embodiments, overlapped description is omitted by assignment of the same reference sign to the same parts.
1. First Embodiment
2. Second Embodiment
3. Modification example

### 1. First Embodiment

### [Configuration of a Display Device]

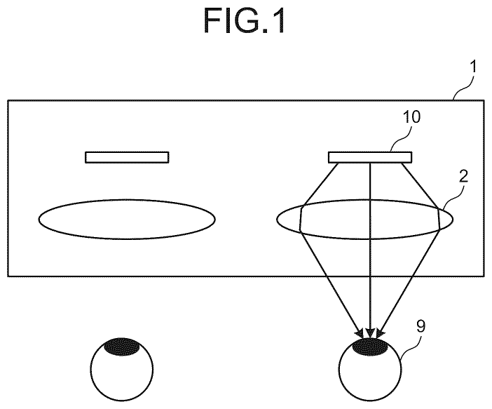

FIG. 1 is a view illustrating a configuration example of a display device according to an embodiment of the present disclosure. The drawing is a schematic view illustrating a configuration example of a display device 1. The display device 1 is configured as an HMD and displays an image of AR or VR for a user. The display device 1 includes a display element 10 and a lens 2. The display element 10 displays an image. The lens 2 captures emission light from the display element 10 and collects the light on an eyeball 9 of the user. A solid arrow in the drawing represents the emission light. The emission light from the central portion of the display element 10 is emitted vertically to the display element 10. The emission light from an end portion of the display element 10 is emitted in an oblique direction with respect to the vertical direction of the display element 10. That is, the emission light from the display element 10 has a diffusion shape. Such emission light is collected by the lens 2 and guided to the eyeball 9. Thus, the user can recognize the enlarged virtual image.

### [Configuration of a Display Element]

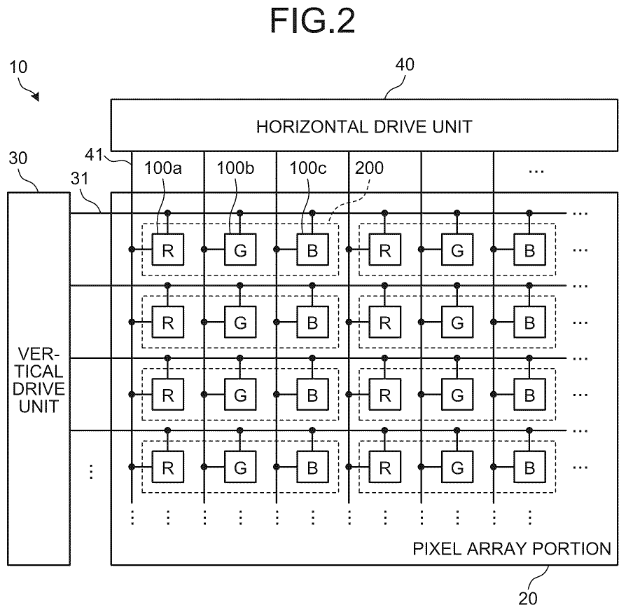

FIG. 2 is a view illustrating a configuration example of a display element according to the embodiment of the present disclosure. The drawing is a block diagram illustrating a configuration example of the display element 10. The display element 10 includes a pixel array portion 20, a vertical drive unit 30, and a horizontal drive unit 40.

The pixel array portion 20 is configured by an arrangement of a plurality of pixels 200 in a shape of a two-dimensional matrix. Each of the pixels 200 in the drawing includes a plurality of subpixels 100. Each of the subpixels 100 emits monochromatic light. The pixel 200 in the drawing includes a subpixel 100a that emits red light, a subpixel 100b that emits green light, and a subpixel 100c that emits blue light. Each of these subpixel 100a and the like includes a light emitting element and a pixel circuit that causes the light emitting element to emit light, and emits light with luminance corresponding to an input image signal. For this light emitting element, for example, an organic EL element can be used. “R”, “G”, and “B” of the subpixels 100 and the like in the drawing represent wavelengths of light respectively emitted by the subpixels 100 and the like.

A signal line 31 and a data line 41 are wired to each of the subpixels 100a, 100b, and 100c. The signal line 31 transmits a control signal of the pixel circuit. The data line 41 transmits an image signal. Note that the signal line 31 is arranged for each row of the shape of the two-dimensional matrix, and is commonly wired to the plurality of subpixels 100 arranged in one row. The data line 41 is arranged for each column of the shape of the two-dimensional matrix, and is commonly wired to the plurality of subpixels 100 arranged in one column.

The vertical drive unit 30 generates the control signal of the subpixels 100 described above. The vertical drive unit 30 in the drawing generates the control signal for each row of the two-dimensional matrix of the pixel array portion 20 and serially performs an output thereof via the signal line 31.

The horizontal drive unit 40 generates the image signal of the subpixels 100 and outputs the generated image signal to the subpixels 100. The horizontal drive unit 40 in the drawing outputs the image signal for each column of the pixel array portion 20 via the data line 41. Note that the image signal is also referred to as a video signal or a luminance signal. Note that the vertical drive unit 30 and the horizontal drive unit 40 are examples of a drive circuit described in claims.

### [Configuration of a Pixel]

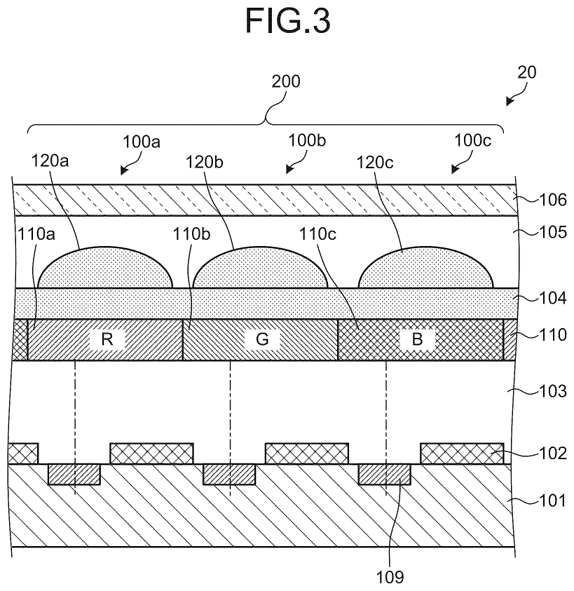

FIG. 3 is a view illustrating a configuration example of a pixel according to the embodiment of the present disclosure. The drawing is a sectional view illustrating a configuration example of each of the pixels 200. As described above, the pixel 200 includes the subpixels 100a, 100b, and 100c. Each of the subpixels 100a and the like includes a substrate 101, a pixel defining film 102, a planarizing film 103, a color filter 110, a protective film 104, an on-chip lens 120, a sealing portion 105, and a glass substrate 106.

The substrate 101 is a substrate that supports the pixel array portion 20. A light emitting element 109 is arranged on the substrate 101 for each of the subpixels 100. For example, an organic EL element can be used as the light emitting element 109.

The pixel defining film 102 is a film that defines a pixel region. An opening is formed in the pixel defining film 102. The light emitting element 109 is arranged in the opening.

The planarizing film 103 is a film that planarizes a surface of the substrate 101. The planarizing film 103 planarizes a surface on which the color filter 110 (described later) is formed.

The color filter 110 is an optical filter that transmits emitted light having a predetermined wavelength among pieces of the emission light from the light emitting element 109. In the subpixel 100a, a color filter 110a that is a color filter that transmits red light is arranged. In the subpixel 100b, a color filter 110b that is a color filter that transmits green light is arranged. In the subpixel 100c, a color filter 110c that is a color filter that transmits blue light is arranged. The light emitting element 109 is an example of a light emitting portion described in claims.

The protective film 104 is a film that protects a surface of the color filter 110. The protective film 104 can be made of the same material as the on-chip lens 120 (described later).

The on-chip lens 120 is a lens that collects the emission light from the light emitting element 109. The on-chip lens 120 has a hemispherical cross section. Note that the on-chip lenses 120 respectively arranged in the subpixels 100a, 100b, and 100c will be referred to as an on-chip lens 120a, an on-chip lens 120b, and an on-chip lens 120c.

The sealing portion 105 seals the pixel 200. Similarly, the glass substrate 106 seals the pixel 200.

The color filters 110a, 110b, and 110c in the drawing are arranged in a manner of being displaced with respect to centers of the subpixel 100a and the like. A dashed-dotted line in the drawing represents a center of the light emitting element 109 which center indicates the center of the subpixel 100a and the like. Furthermore, different values can be set for the subpixels 100a, 100b, and 100c as the displacement in the arrangement of the color filters 110. An example of a case where the displacement in the arrangement of the color filter 110c in the subpixel 100c is larger than the displacement in the arrangement of the color filter 110a in the subpixel 100a and the color filter 110b in the subpixel 100b is illustrated in the drawing. Furthermore, the on-chip lens 120a in the drawing is arranged in a displaced manner, similarly to the color filter 110a. The on-chip lens 120b and the on-chip lens 120c are similarly arranged in a displaced manner.

### [Configuration of a Pixel Array Portion]

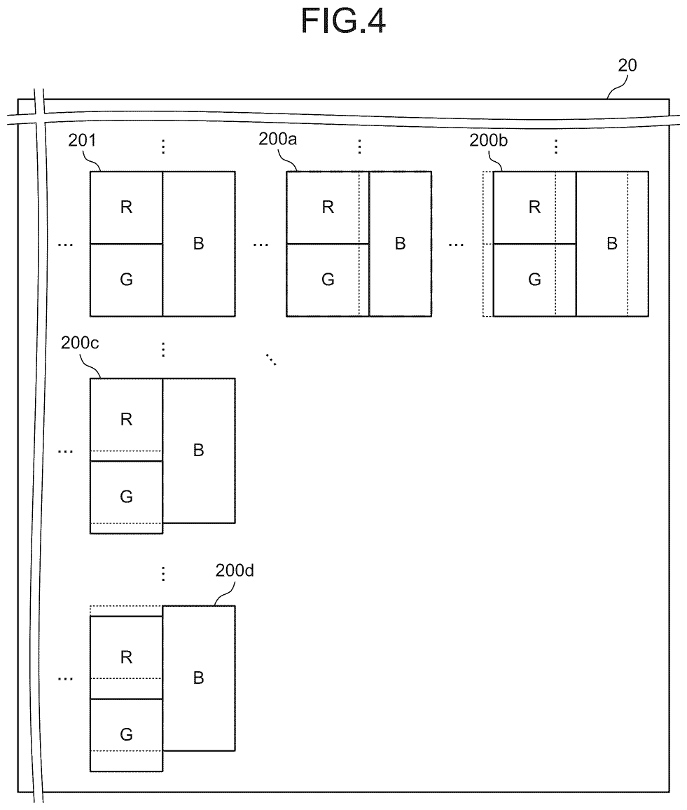

FIG. 4 is a view illustrating a configuration example of the pixel array portion according to the first embodiment of the present disclosure. The drawing is a view illustrating a configuration example of the pixel array portion 20, and is a view illustrating a state of the pixels 200 arranged in the pixel array portion 20. Rectangles, to which “R”, “G”, and “B” are attached, of each of the pixels 200 in the drawing represent the subpixel 100a, the subpixel 100b, and the subpixel 100c, respectively. Note that the pixels 200 in the drawing are an example configured in a substantially square shape. Furthermore, the subpixel 100c in the drawing has a rectangular shape in contact with three sides including one side of the substantially square shape. Furthermore, an example of a shape in which the subpixels 100c are adjacent to each other in the pixels 201 and 200 adjacent to each other in a column direction is illustrated in the drawing. Note that the subpixel 100c is an example of a second subpixel described in claims.

A pixel arranged at a center of the pixel array portion 20 is referred to as a pixel 201. This pixel 201 is a pixel in which the color filter 110a and the like are arranged at centers of the subpixels 100 (light emitting element 109) in the subpixel 100a and the like.

As described above, in the pixel 200, the color filter 110 and the like are arranged in a manner of being displaced from the centers of the subpixels 100 (light emitting element 109) in the subpixel 100a and the like. A direction in which the arrangement of the color filters 110 and the like is displaced is a direction from the center of the pixel array portion 20 toward a peripheral portion. Furthermore, a displacement amount of the arrangement of the color filters 110 and the like can be increased toward the peripheral portion of the pixel array portion 20.

The pixels 200a and 200b in the drawing are the pixels 200 arranged in a lateral direction passing through the center of the pixel array portion 20. Furthermore, the pixels 200c and 200d are the pixels 200 arranged in a longitudinal direction passing through the center of the pixel array portion 20. Broken lines in these pixel 200a and the like indicate positions of the color filter 110a and the like of a case where the displacement is not performed. In the pixels 200a and 200b, the color filter 110a and the like are arranged in a manner of being displaced in a right direction of the drawing. Furthermore, in the pixels 200c and 200d, the color filter 110a and the like are arranged in a manner of being displaced in a downward direction of the drawing. Note that in the pixel 200 arranged in an oblique direction with respect to the center of the pixel array portion 20, the color filter 110a and the like are arranged in a manner of being displaced in the oblique direction.

As illustrated in the drawing, in the pixel 200a and the like, the color filters 110 can be displaced for different amounts in the arrangement depending on the subpixels 100. For example, in the pixel 200d, the displacement amount of the subpixel 100b of the color filter 110b is the largest, and the displacement amount of the subpixel 100a of the color filter 110a follows. Note that the subpixel 100c of the pixel 200 represents an example of a case where the arrangement position of the color filter 110c is not displaced.

### [Configuration of a Pixel]

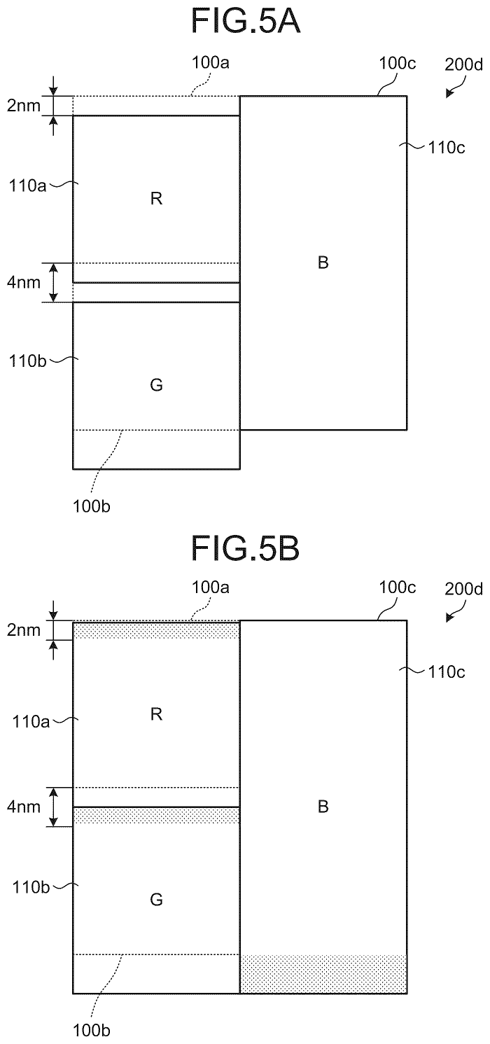

FIGS. 5A and 5B are plan views illustrating configuration examples of the pixel according to the first embodiment of the present disclosure. The drawings are views illustrating a configuration example of the pixel 200, and are views illustrating displacement in arrangement of the color filter 110a and the like. Furthermore, a case of the pixel 200d in FIG. 4 is illustrated in the drawings. The displacement in the arrangement of the color filters 110a and the like will be described with the pixel 200d as an example.

In FIG. 5A, the color filter 110a of the subpixel 100a is arranged in a manner of being displaced by 2 nm in the downward direction of the drawing. Furthermore, the color filter 110b of the subpixel 100b is arranged in a manner of being displaced by 4 nm in the downward direction of the drawing. Note that the subpixel 100c represents an example of a case where the color filter 110c is arranged at the center of the subpixel 100b. As described above, in the pixel 200d in the drawing, the color filters 110 can be arranged with different displacement amounts depending on the subpixels 100. On the other hand, since the displacement amounts of the color filters 110 vary depending on each of the subpixels 100, a gap is generated between the color filters 110.

FIG. 5B is a view illustrating an example in which the above-described gap is filled with the adjacent color filter 110. Hatched regions in the drawing represent regions filled with the adjacent color filters 110. An upper gap of the color filter 110a in the drawing can be filled with the color filter 110a. In addition, an upper gap of the color filter 110b in the drawing can be filled with the color filter 110b. In addition, a lower gap of the color filter 110c in the drawing can be filled with the color filter 110c.

Note that it is also possible to employ a configuration in which the gap is filled with a light blocking portion that blocks the emission light.

### [Luminance Characteristic]

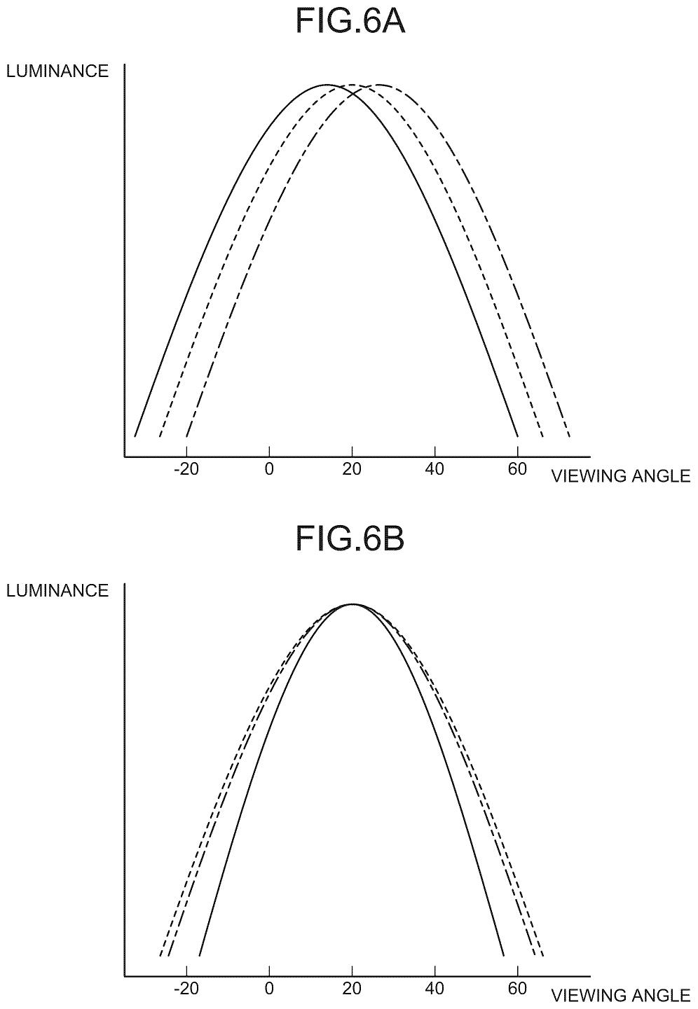

FIGS. 6A and 6B are graphs for describing luminance characteristics of the subpixels according to the first embodiment of the present disclosure. FIGS. 6A and 6B are graphs illustrating a relation between luminance and a viewing angle of the subpixel 100a and the like. In the drawings, a vertical axis represents relative luminance, and a horizontal axis represents the viewing angle. The value “0” on the horizontal axis in the drawing represents a direction vertical to the pixel array portion 20. In addition, a solid line graph in the drawing represents a characteristic of the subpixel 100c corresponding to the blue light, a dotted line graph represents a characteristic of the subpixel 100a corresponding to the red light, and a dashed-dotted line graph represents a characteristic of the subpixel 100b corresponding to the green light. Furthermore, an example of a case where white light is emitted in the pixel 200 is illustrated in the drawing.

FIG. 6A is a graph illustrating, as a comparative example, a characteristic of a case where the displacement amounts in the arrangement of the color filter 110a and the like are equal in the pixel 200d and the like. The pixel 200 in the drawing has a characteristic that each of the optical axes of the red light, the green light, and the blue light is displaced. Thus, in the pixel 200 in the drawing, color shift is generated when light is emitted in the oblique direction. This is because an emission angle of the emission light changes due to a difference in refractive indexes of the color filters 110a, 110b, and 110c.

FIG. 6B is a graph illustrating a characteristic of a case where the displacement amount is adjusted for each of the color filters 110 in the pixel 200d and the like. By adjusting the displacement amount in accordance with the characteristics of the color filters 110, it is possible to align the optical axes of the red light, green light, and blue light. Note that the blue light in the drawing has a shape with a narrow slope as compared with the red light and the green light. As will be described later, this can be corrected by adjustment of the on-chip lens 120c of the subpixel 100c corresponding to the blue light.

As described above, the display element 10 of the first embodiment of the present disclosure can align the optical axes of the subpixels 100 by adjustment of the position of the color filter 110 for each of the subpixels 100. As a result, the display image quality of the display element 10 can be improved.

### 2. Second Embodiment

In the display element 10 of the first embodiment described above, the color filter 110 is arranged in a manner of being displaced for each of the subpixels 100. On the other hand, a display element 10 of the second embodiment of the present disclosure is different from that of the above-described first embodiment in a point that an on-chip lens 120 is further arranged in a manner of being displaced for each of subpixels 100.

### [Configuration of a Pixel]

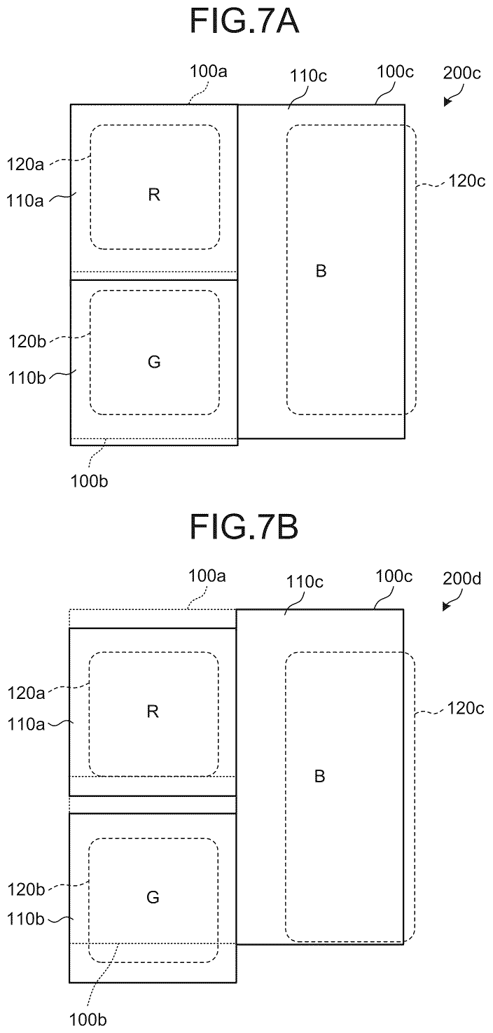

FIGS. 7A and 7B are plan views illustrating configuration examples of a pixel according to the second embodiment of the present disclosure. The drawings are views illustrating configuration examples of a pixel 200 similarly to FIGS. 5A and 5B. A case of the pixel 200c in FIG. 4 is illustrated in FIG. 7A. A case of the pixel 200d in FIG. 4 is illustrated in FIG. 7B.

In the pixel 200c in FIG. 7A, an example in which a displacement amount of an on-chip lens 120a of a subpixel 100a is 0 is illustrated. Similarly, a displacement amount of an on-chip lens 120b of a subpixel 100b can also be set to 0. On the other hand, an on-chip lens 120c of a subpixel 100c is arranged in a manner of being displaced in a right direction of the drawing.

In the pixel 200d in FIG. 7B, an example in which a displacement amount of the on-chip lens 120a of the subpixel 100a is the same as that of the color filter 110a is illustrated. Similarly, a displacement amount of the on-chip lens 120b of the subpixel 100b can also be set to 0 that is the same as that of the color filter 110b. Furthermore, the on-chip lens 120c of the subpixel 100c is arranged in a manner of being displaced in a lower right direction of the drawing.

Note that it is also possible to employ a configuration in which the arrangement of the on-chip lens 120c and the like is displaced without the arrangement of the color filter 110a and the like being displaced.

As described above, in the subpixel 100c, by arranging the on-chip lens 120c in a manner of being displaced with respect to the color filter 110c, it is possible to relax collection of emission light by the on-chip lens 120c, and to widen the slope of the blue light described above. Note that the correction of the characteristic (slope) of the emission light by the adjustment of the on-chip lens 120 can also be performed with respect to the subpixels 100a and 100b.

### [Arrangement of the Pixels]

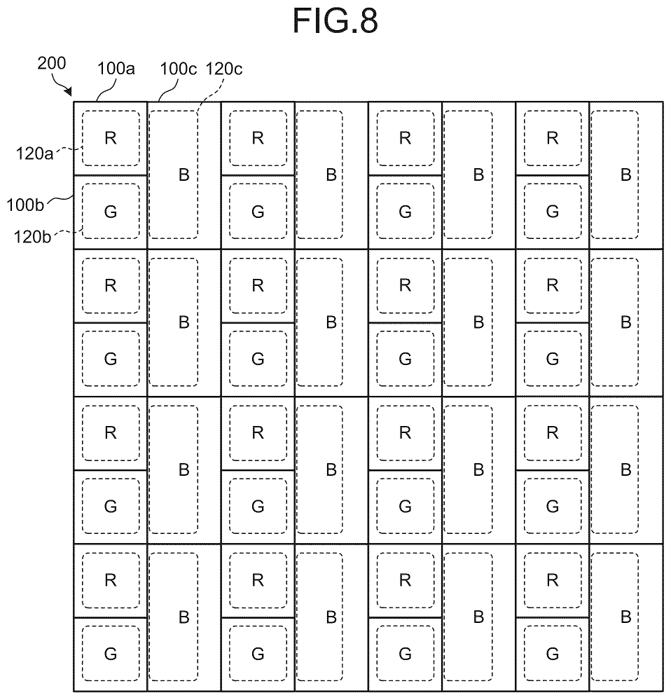

FIG. 8 is a plan view illustrating an arrangement example of pixels according to the second embodiment of the present disclosure. The drawing is a view illustrating an arrangement example of the pixels 200. As illustrated in the drawing, the on-chip lenses 120c can be arranged on the same side (left side in the drawing) of the subpixels 100c.

Since the configuration of the display element 10 other than this is similar to the configuration of the display element 10 in the first embodiment of the present disclosure, description thereof is omitted.

As described above, in the display element 10 of the second embodiment of the present disclosure, the characteristic of the emission light can be corrected by displacement of the arrangement of the on-chip lens 120 in addition to the color filter 110a and the like. As a result, display image quality of the display element 10 can be further improved.

### 3. Modification Example

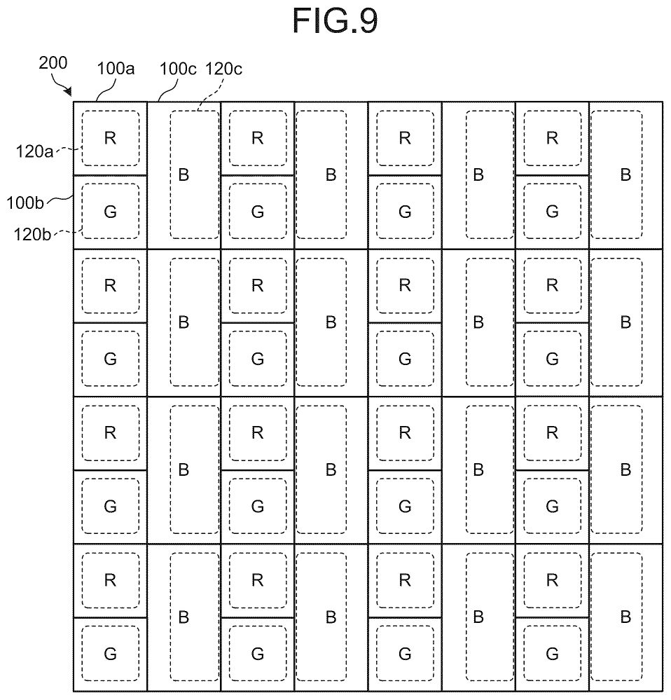

A modification example of the display element of the second embodiment described above will be described. FIGS. 9 to 27 are plan views illustrating configuration examples of pixels according to modification examples of the embodiment of the present disclosure.

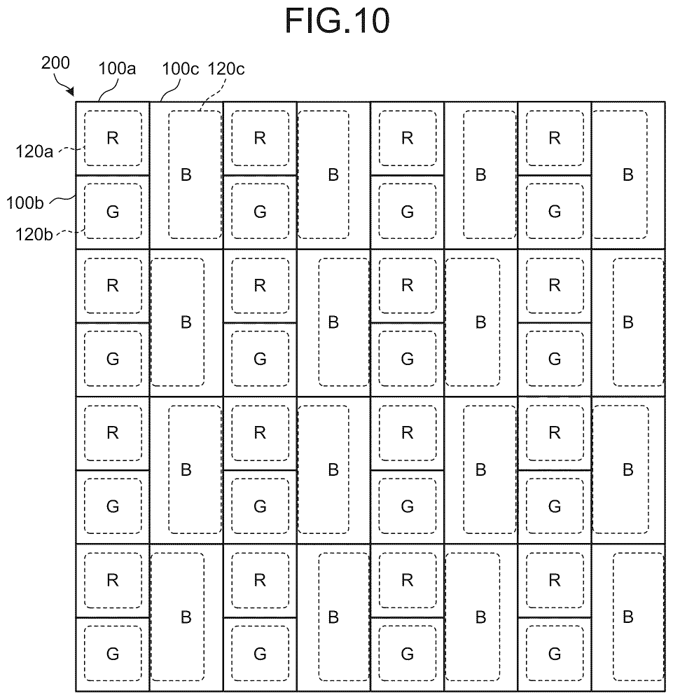

FIGS. 9 and 10 are plan views illustrating modification examples of the pixel 200 in FIG. 8. In FIG. 9, on-chip lenses 120c are arranged on different sides depending on each columns. An example in which on-chip lenses 120c are arranged on different sides depending on each rows and columns is illustrated in FIG. 10. Unlike FIG. 8, since the on-chip lenses 120c are alternately arranged on different sides, it is possible to reduce generation of vertical stripes and moire caused by the on-chip lenses 120c.

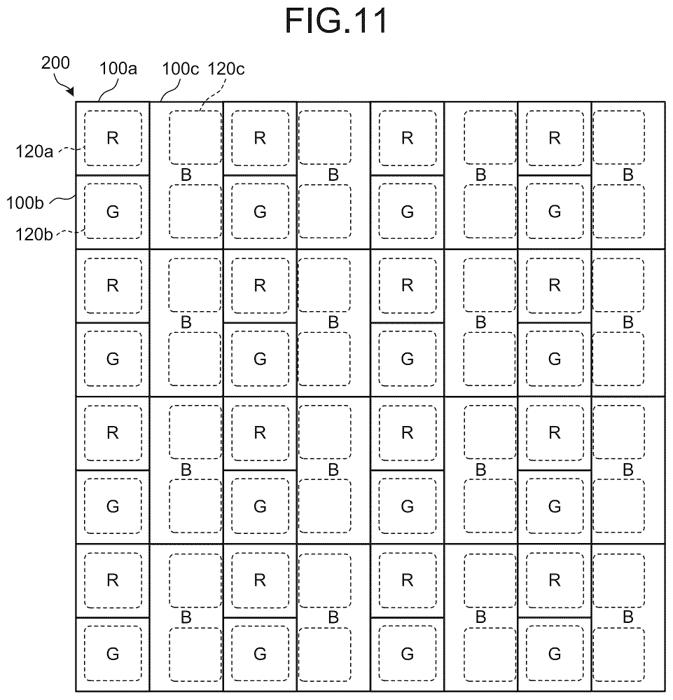

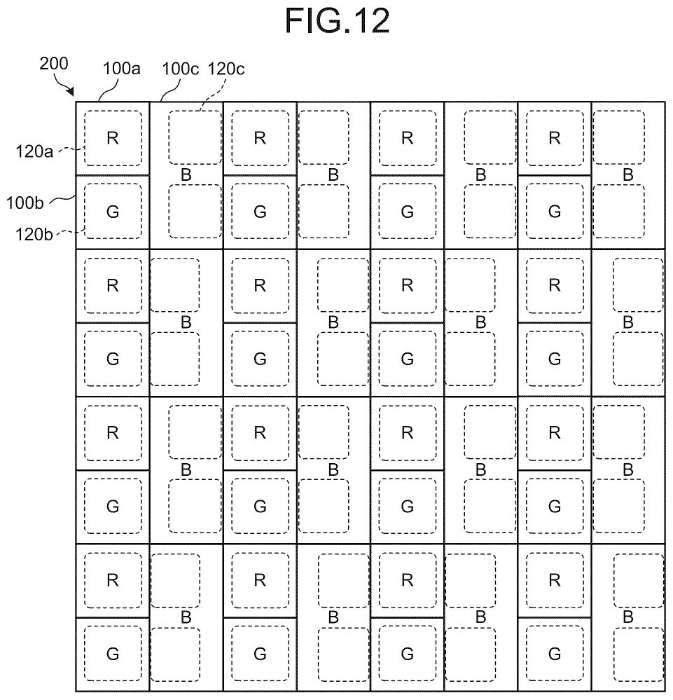

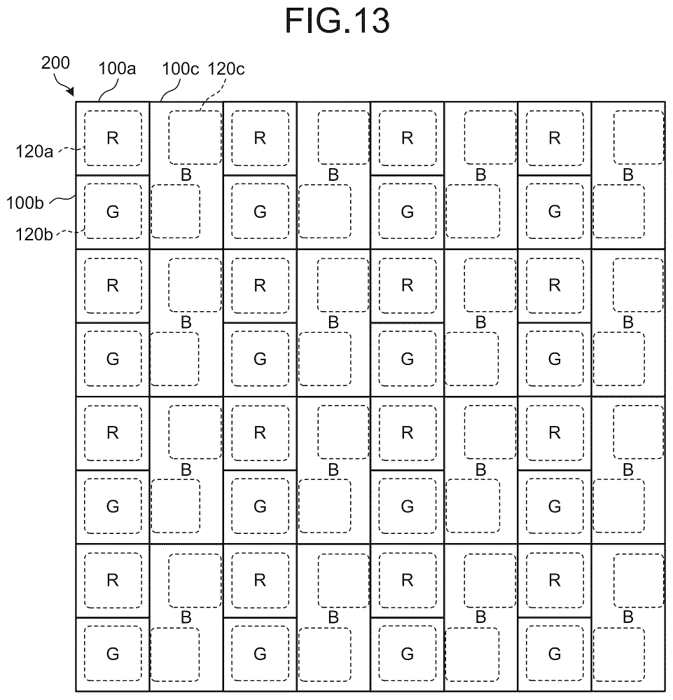

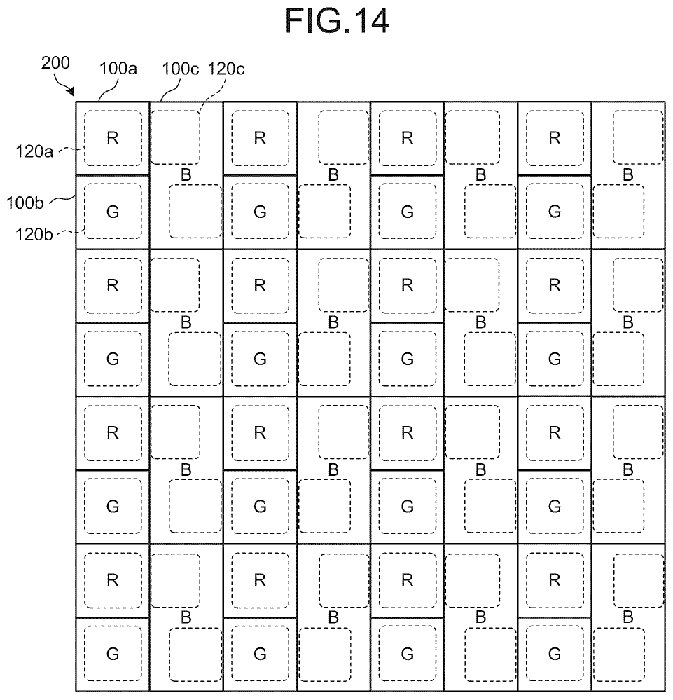

Examples in which a plurality of on-chip lenses 120c is arranged in a subpixel 100c are illustrated in FIGS. 11 to 14. An example in which two on-chip lenses 120c are arranged on the same side of the subpixel 100c is illustrated in FIG. 11. Furthermore, the on-chip lenses 120c in the drawing are arranged on different sides depending on each columns. An example in which the two on-chip lenses 120c are arranged on different sides depending on each rows and columns is illustrated in FIG. 12. Furthermore, examples in which the two on-chip lenses 120c are arranged in a manner of being displaced to different sides of the subpixel 100c are illustrated in FIGS. 13 and 14. The pixel array portion 20 in FIGS. 13 and 14 can reduce generation of vertical stripes and moire caused by the on-chip lenses 120c, similarly to FIG. 10.

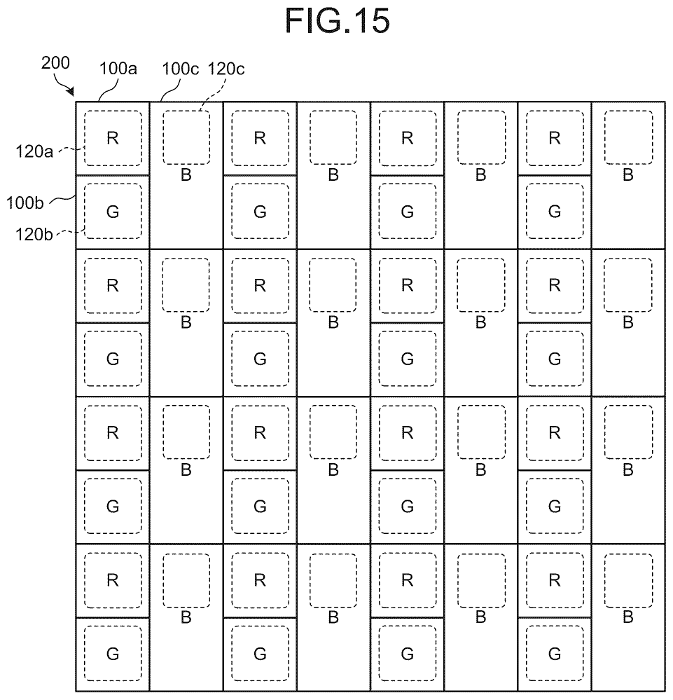

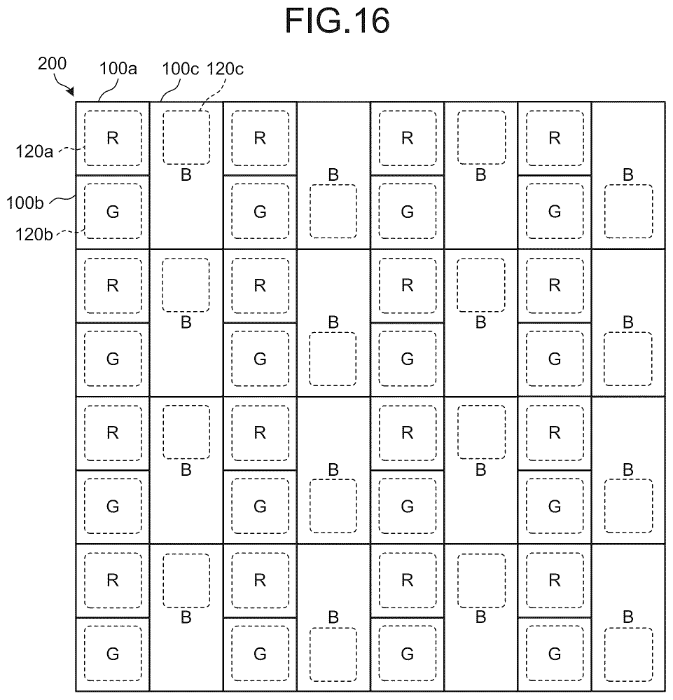

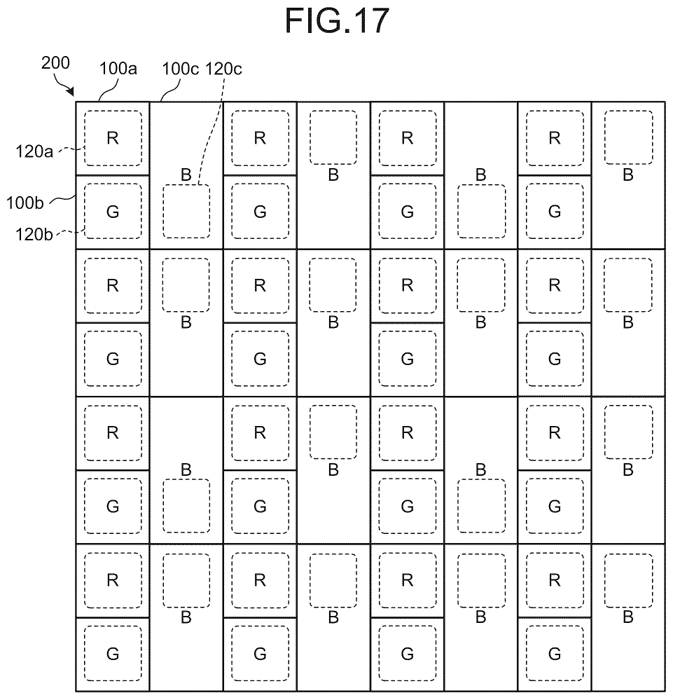

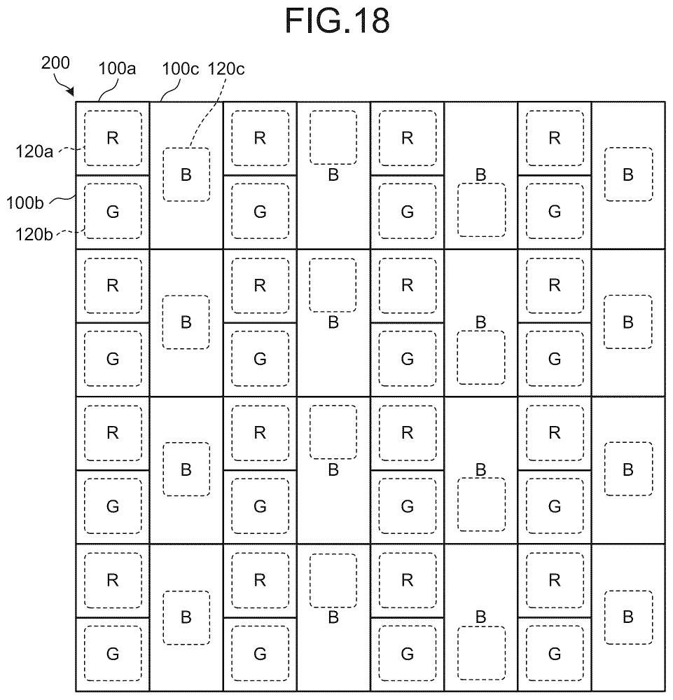

Examples in which an on-chip lens 121 having a size equal to or smaller than a half of a subpixel is arranged in the subpixel 100c are illustrated in FIGS. 15 to 18. An example in which the on-chip lenses 121 are arranged in a manner of being displaced to an upper side of the subpixels 100c is illustrated in FIG. 15. An example of a case where the on-chip lenses 121 are arranged on the upper side or a lower side of the subpixels 100c and the arrangement positions are changed depending on each columns is illustrated in FIG. 16. An example in which the arrangements of the on-chip lenses 121 in FIGS. 15 and 16 are combined is illustrated in FIG. 17. An example of a case where the on-chip lenses 121 are arranged on the upper side, a center, and the lower side of the subpixels 100c is illustrated in FIG. 18. Furthermore, an example of a case where the arrangement positions of the on-chip lenses 121 vary depending on each columns is illustrated in the drawing.

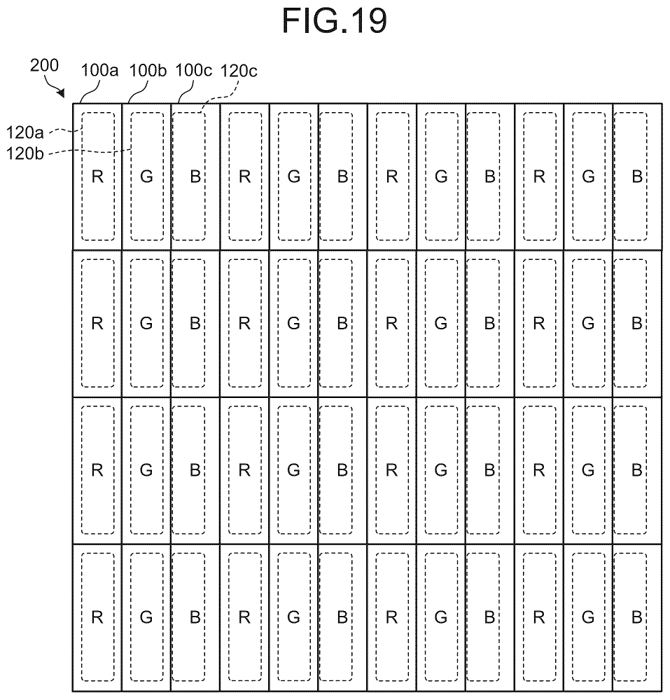

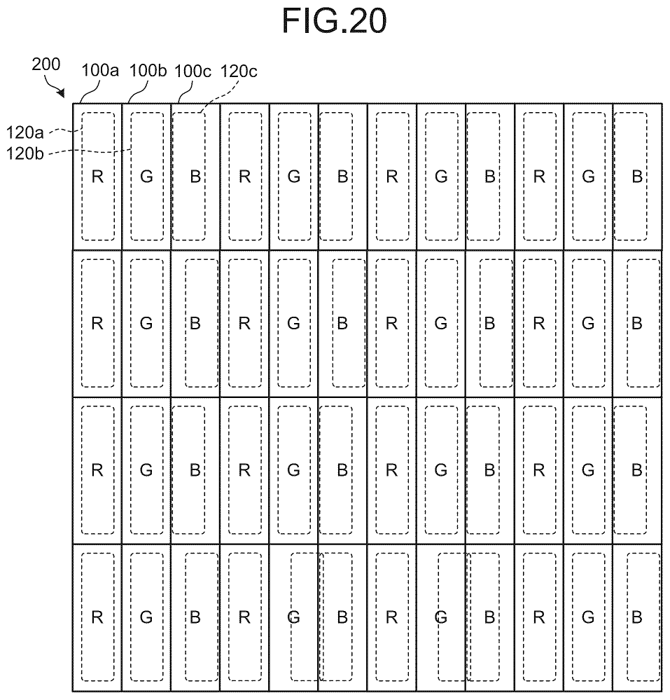

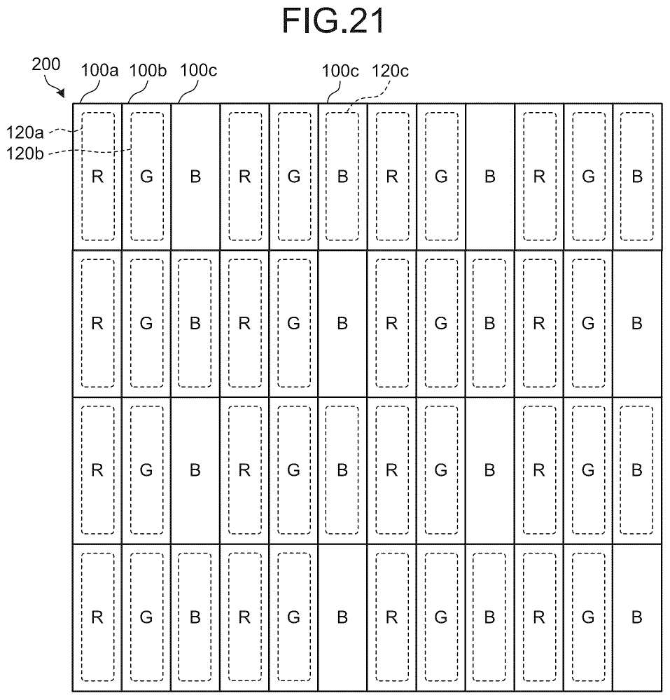

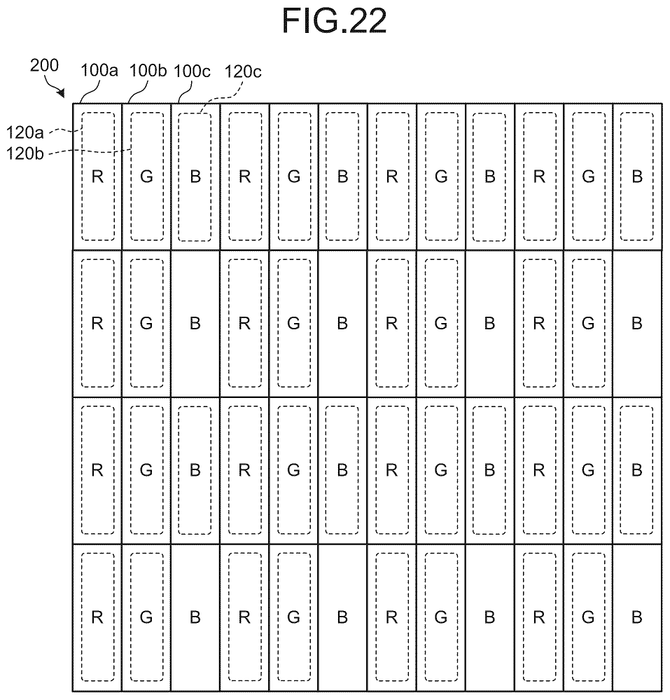

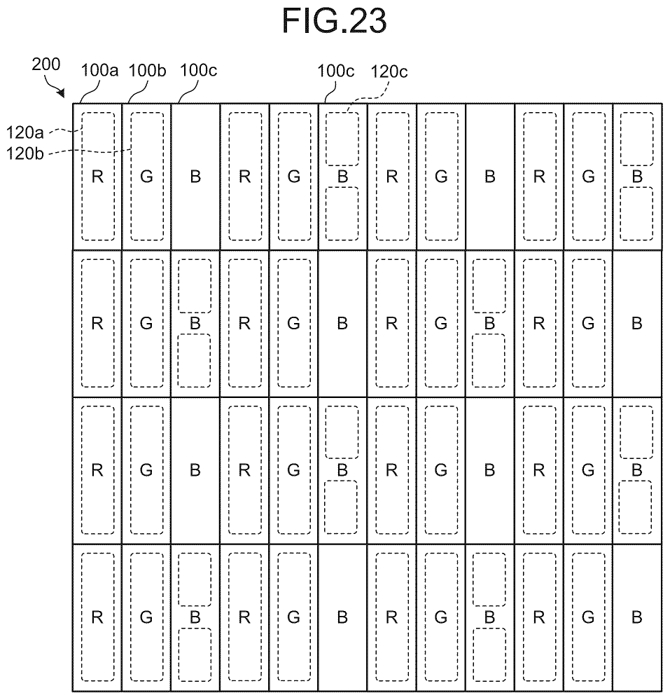

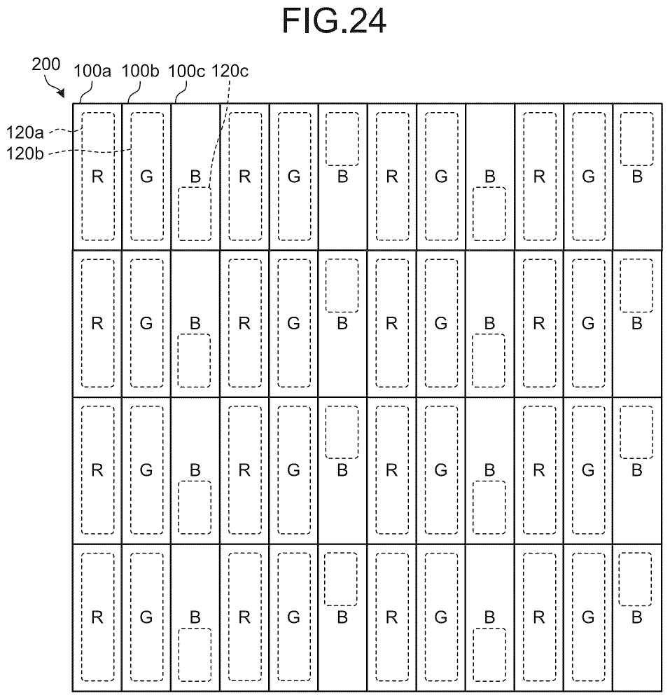

Examples of a pixel 200 including a subpixel 100a and the like having a rectangular shape of the same size are illustrated in FIGS. 19 to 24. An example of a case where on-chip lenses 120c are arranged on the same side of subpixels 100c is illustrated in FIG. 19. An example of a case where arrangement positions of the on-chip lenses 120c vary depending on each rows and columns is illustrated in FIG. 20. Examples of a case of including a subpixel 100c in which the on-chip lens 120c is omitted are illustrated in FIGS. 21 and 22. An example of a case where a subpixel 100c in which the on-chip lens 120c is omitted and a subpixel 100c including two on-chip lenses 120c are included is illustrated in FIG. 23. An example of a case where a subpixel 100c including an on-chip lens 121 is included is illustrated in FIG. 24.

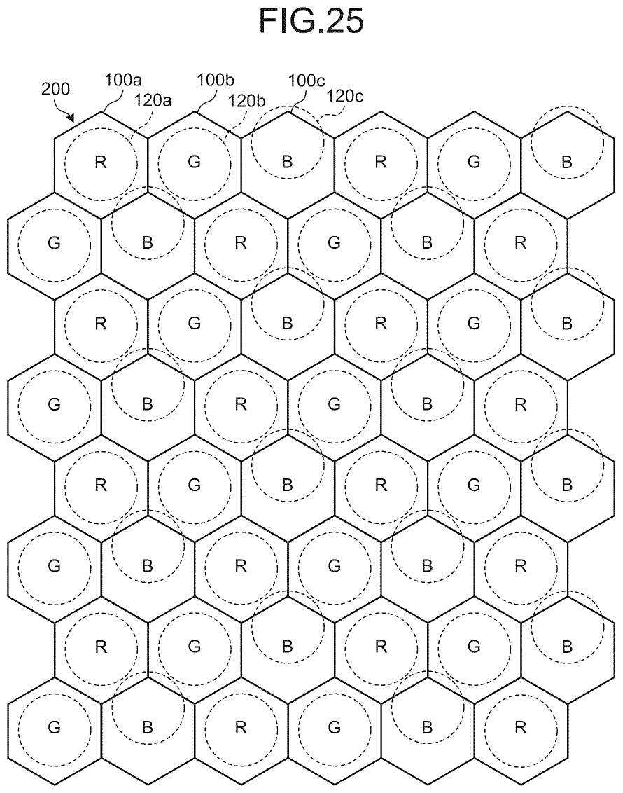

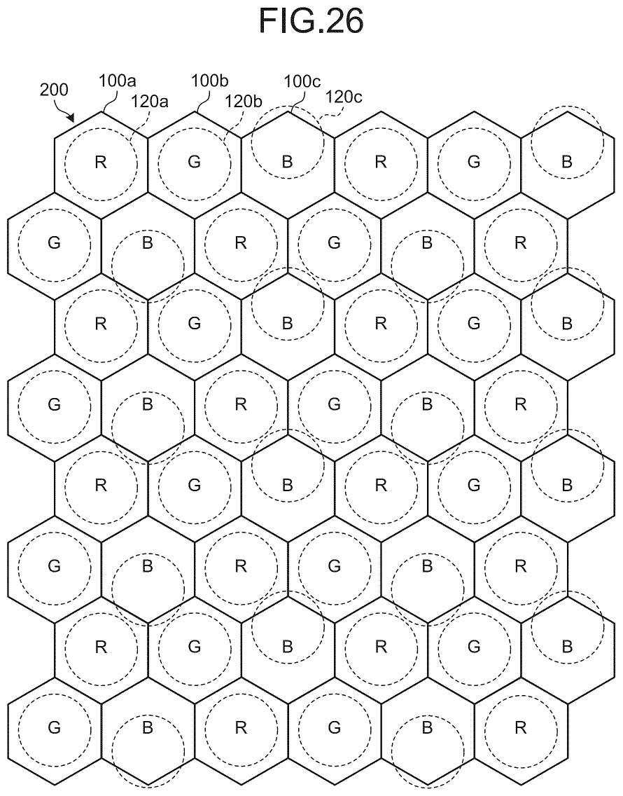

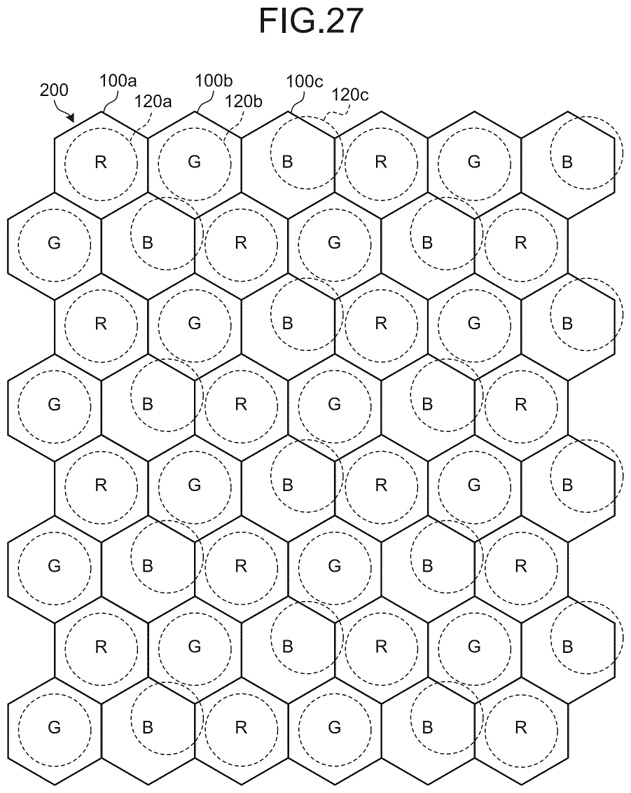

Examples of a pixel array portion 20 in which a subpixel 100a and the like having a hexagonal shape in plan view are delta-arranged are illustrated in FIGS. 25 to 27. Furthermore, an on-chip lens 120a and the like in the drawing can be formed in a circular shape in plan view. An example in which on-chip lenses 120c are arranged in a manner of being displaced on an upper side in the drawing of subpixels 100c is illustrated in FIG. 25. An example of a case where the on-chip lenses 120c are arranged in a manner of being alternately displaced to the upper side and a lower side of the subpixels 100c is illustrated in FIG. 26. An example of a case where the on-chip lenses 120c are arranged in a manner of being displaced to an upper right in the drawing of the subpixels 100c is illustrated in FIG. 27.

Since the configuration of the display element 10 other than this is similar to the configuration of the display element 10 in the first embodiment of the present disclosure, description thereof is omitted.

Note that the effects described in the present description are merely examples and are not limitations, and there may be another effect.

Note that the present technology can also have the following configurations.

(1)

A display element comprising:
a pixel array portion in which a plurality of pixels is arranged, each of the pixels including a plurality of subpixels each of which includes a light emitting portion and a color filter that transmits emission light of a predetermined wavelength among pieces of the emission light from the light emitting portion, wherein
the plurality of pixels includes the plurality of subpixels respectively including the color filters corresponding to different wavelengths, and
the pixel array portion includes at least one of the pixels in which the color filters are arranged in a manner of being displaced with respect to centers of the own light emitting portions and the displacement in the arrangement of the color filters vary depending on each of the plurality of subpixels.
   (2)

The display element according to the above (1), wherein
each of the pixels includes a red subpixel including a red color filter that is the color filter that transmits red light, a green subpixel including a green color filter that is the color filter that transmits green light, and a blue subpixel including a blue color filter that is the color filter that transmits blue light.
   (3)

The display element according to the above (1) or (2), wherein
each of the pixels includes the plurality of subpixels each of which further includes an on-chip lens that collects the emission light, and
the pixel array portion includes at least one of the pixels in which the on-chip lenses are arranged in a manner of being displaced with respect to the centers of the own light emitting portions and the displacement in the arrangement of the on-chip lenses vary depending on each of the plurality of subpixels.
   (4)

The display element according to any one of the above (1) to (3), wherein
each of the pixels has a substantially square shape in plan view.
   (5)

The display element according to the above (4), wherein
each of the pixels includes a second subpixel that is the subpixel configured in a rectangular shape in contact with three sides including one side of the substantially square shape.
   (6)

The display element according to the above (5), wherein
the pixels are arranged in a matrix shape in the pixel array portion, and
the pixels are configured in a shape in which the second subpixels are adjacent between the pixels adjacent in a column direction of the matrix shape.
   (7)

The display element according to any one of the above (3) to (6), wherein
the pixels are arranged in a matrix shape in the pixel array portion, and
each of the pixels includes a second subpixel in which the on-chip lens is arranged in a manner of being displaced in any of row and column directions of the matrix shape.
   (8)

The display element according to the above (7), wherein
the pixels include the second subpixels in which the on-chip lenses are arranged in a manner of being displaced in different directions depending on each columns of the matrix shape.
   (9)

The display element according to the above (7), wherein
the pixels include the second subpixels in which the on-chip lenses are arranged in a manner of being displaced in different directions depending on each rows of the matrix shape.
   (10)

The display element according to the above (7), wherein
each of the pixels includes the second subpixel including a plurality of the on-chip lenses.
   (11)

The display element according to the above (10), wherein
each of the pixels includes the second subpixel in which the plurality of on-chip lenses is arranged in a manner of being displaced in any of the row and column directions of the matrix shape.
   (12)

The display element according to the above (11), wherein
the pixels include the second subpixels in which the plurality of on-chip lenses is arranged in a manner of being displaced in different directions depending on each columns of the matrix shape.
   (13)

The display element according to the above (11), wherein
the pixels include the second subpixels in which the plurality of on-chip lenses is arranged in a manner of being displaced in different directions depending on each rows of the matrix shape.
   (14)

The display element according to the above (11), wherein
the pixels include the second subpixels in which the plurality of on-chip lenses is arranged in a manner of being displaced in different row directions of the matrix shape.
   (15)

The display element according to any one of the above (4) to (14), wherein
the pixels include the subpixels configured in a rectangular shape.
   (16)

The display element according to any one of the above (1) to (3), wherein
each of the pixels has a substantially hexagonal shape in plan view.
   (17)

A display device comprising:
a display element including a pixel array portion in which a plurality of pixels is arranged, each of the pixels including a plurality of subpixels each of which includes a light emitting portion and a color filter that transmits emission light of a predetermined wavelength among pieces of the emission light from the light emitting portion, in which
the plurality of pixels includes the plurality of subpixels respectively including the color filters corresponding to different wavelengths, and
the pixel array portion includes at least one of the pixels in which the color filters are arranged in a manner of being displaced with respect to centers of the own light emitting portions and the displacement in the arrangement of the color filters vary depending on each of the plurality of subpixels; and
a drive circuit that drives the subpixels.

### REFERENCE SIGNS LIST

1 DISPLAY DEVICE
10 DISPLAY ELEMENT
20 PIXEL ARRAY PORTION
30 VERTICAL DRIVE UNIT
40 HORIZONTAL DRIVE UNIT
100, 100a, 100b, 100c SUBPIXEL
109 LIGHT EMITTING ELEMENT
110, 110a, 110b, 110c COLOR FILTER
120, 120a, 120b, 120c, 121 ON-CHIP LENS
200, 200a, 200b, 200c, 200d, 201 PIXEL

1. A display element comprising:
a pixel array portion in which a plurality of pixels is arranged, each of the pixels including a plurality of subpixels each of which includes a light emitting portion and a color filter that transmits emission light of a predetermined wavelength among pieces of the emission light from the light emitting portion, wherein
the plurality of pixels includes the plurality of subpixels respectively including the color filters corresponding to different wavelengths, and
the pixel array portion includes at least one of the pixels in which the color filters are arranged in a manner of being displaced with respect to centers of the own light emitting portions and the displacement in the arrangement of the color filters vary depending on each of the plurality of subpixels.

2. The display element according to claim 1, wherein
each of the pixels includes a red subpixel including a red color filter that is the color filter that transmits red light, a green subpixel including a green color filter that is the color filter that transmits green light, and a blue subpixel including a blue color filter that is the color filter that transmits blue light.

3. The display element according to claim 1, wherein
each of the pixels includes the plurality of subpixels each of which further includes an on-chip lens that collects the emission light, and
the pixel array portion includes at least one of the pixels in which the on-chip lenses are arranged in a manner of being displaced with respect to the centers of the own light emitting portions and the displacement in the arrangement of the on-chip lenses vary depending on each of the plurality of subpixels.

4. The display element according to claim 1, wherein
each of the pixels has a substantially square shape in plan view.

5. The display element according to claim 4, wherein
each of the pixels includes a second subpixel that is the subpixel configured in a rectangular shape in contact with three sides including one side of the substantially square shape.

6. The display element according to claim 5, wherein
the pixels are arranged in a matrix shape in the pixel array portion, and
the pixels are configured in a shape in which the second subpixels are adjacent between the pixels adjacent in a column direction of the matrix shape.

7. The display element according to claim 3, wherein
the pixels are arranged in a matrix shape in the pixel array portion, and
each of the pixels includes a second subpixel in which the on-chip lens is arranged in a manner of being displaced in any of row and column directions of the matrix shape.

8. The display element according to claim 7, wherein
the pixels include the second subpixels in which the on-chip lenses are arranged in a manner of being displaced in different directions depending on each columns of the matrix shape.

9. The display element according to claim 7, wherein
the pixels include the second subpixels in which the on-chip lenses are arranged in a manner of being displaced in different directions depending on each rows of the matrix shape.

10. The display element according to claim 7, wherein
each of the pixels includes the second subpixel including a plurality of the on-chip lenses.

11. The display element according to claim 10, wherein
each of the pixels includes the second subpixel in which the plurality of on-chip lenses is arranged in a manner of being displaced in any of the row and column directions of the matrix shape.

12. The display element according to claim 11, wherein
the pixels include the second subpixels in which the plurality of on-chip lenses is arranged in a manner of being displaced in different directions depending on each columns of the matrix shape.

13. The display element according to claim 11, wherein
the pixels include the second subpixels in which the plurality of on-chip lenses is arranged in a manner of being displaced in different directions depending on each rows of the matrix shape.

14. The display element according to claim 11, wherein
the pixels include the second subpixels in which the plurality of on-chip lenses is arranged in a manner of being displaced in different row directions of the matrix shape.

15. The display element according to claim 4, wherein
the pixels include the subpixels configured in a rectangular shape.

16. The display element according to claim 1, wherein
each of the pixels has a substantially hexagonal shape in plan view.

17. A display device comprising:
a display element including a pixel array portion in which a plurality of pixels is arranged, each of the pixels including a plurality of subpixels each of which includes a light emitting portion and a color filter that transmits emission light of a predetermined wavelength among pieces of the emission light from the light emitting portion, in which
the plurality of pixels includes the plurality of subpixels respectively including the color filters corresponding to different wavelengths, and
the pixel array portion includes at least one of the pixels in which the color filters are arranged in a manner of being displaced with respect to centers of the own light emitting portions and the displacement in the arrangement of the color filters vary depending on each of the plurality of subpixels; and
a drive circuit that drives the subpixels.
